(19) United States
(12) Patent Application Publication
(10) Pub. No.: US 2018/0013021 A1
(43) Pub. Date: Jan. 11, 2018

(54) SOLAR CELL

(71) Applicant: Panasonic Intellectual Property Management Co., Ltd., Osaka-shi (JP)

(72) Inventor: Motohide KAI, Osaka (JP)

(21) Appl. No.: 15/706,605

(22) Filed: Sep. 15, 2017

Related U.S. Application Data
(63) Continuation of application No. PCT/JP2016/000942, filed on Feb. 23, 2016.

(30) Foreign Application Priority Data
Mar. 17, 2015 (JP) 2015-053809

(51) Int. Cl. H01L 31/0376; H01L 31/0236; H01L 31/0216; H01L 31/0224; H01L 31/20; H01L 31/0747

(52) U.S. Cl. CPC H01L 31/03762; H01L 31/202; H01L 31/0747; H01L 31/02167; H01L 31/022441; H01L 31/02363; H01L 31/02168

(57) ABSTRACT

A solar cell includes: a semiconductor substrate formed of n-type crystalline silicon; a first stack formed of amorphous silicon in a first region on a first principle surface of the semiconductor substrate; a second stack formed of amorphous silicon in a second region different from the first region on the first principle surface; and a third stack formed of amorphous silicon on a second principle surface of the semiconductor substrate opposite from the first principle surface. The second stack has an oxygen concentration that is higher than that of the first stack.

### RELATED APPLICATION

Priority is claimed to Japanese Patent Application No. 2015-053809, filed on Mar. 17, 2015, the entire content of which is incorporated herein by reference.

### BACKGROUND

### 1. Field of the Invention

The present invention relates to a solar cell and particularly to a back surface junction type solar cell.

### 2. Description of the Related Art

Solar cells having high power generation efficiency include back surface junction type solar cells with an n-type semiconductor layer and a p-type semiconductor layer formed on a back surface thereof, which is opposite to a light-receiving surface on which light becomes incident. On principle surfaces on the side of a light-receiving surface and on the side of a back surface of a semiconductor substrate, an intrinsic amorphous semiconductor layer is provided. Further, a structure is known where the oxygen concentration at an interface portion between the semiconductor substrate and the amorphous semiconductor layer is increased in order to improve the output characteristics of a solar cell.

### SUMMARY

In a back surface junction type solar cell, the concentration of oxygen included in an amorphous semiconductor layer is desirably adjusted in an appropriate manner.

In this background, a purpose of the present invention is to provide a solar cell with improved output characteristics.

A solar cell according to one embodiment of the present invention includes: a semiconductor substrate formed of n-type crystalline silicon; a first stack formed of amorphous silicon in a first region on a first principle surface of the semiconductor substrate; a second stack formed of amorphous silicon in a second region different from the first region on the first principle surface; and a third stack formed of amorphous silicon on a second principle surface of the semiconductor substrate opposite from the first principle surface. The second stack has an oxygen concentration that is higher than that of the first stack.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a plan view illustrating a solar cell according to an embodiment;

FIG. 2 is a cross-sectional view illustrating the structure of a solar cell according to the embodiment.

### DETAILED DESCRIPTION

The invention will now be described by reference to the preferred embodiments. This does not intend to limit the scope of the present invention, but to exemplify the invention.

A brief description is now given before focusing on specific features of the present invention. An embodiment of the present invention relates to a back surface junction type solar cell, and an n-type first region and a p-type second region are provided on a first principle surface of a semiconductor substrate, which corresponds to the back surface side opposite to the light-receiving surface. On the first region, a first i-type layer formed of i-type amorphous silicon and a first conductivity type layer formed of n-type amorphous silicon are stacked successively. On the second region, a second i-type layer formed of i-type amorphous silicon and a second conductivity type layer formed of p-type amorphous silicon are stacked successively. In the present embodiment, by increasing the oxygen concentration of the second i-type layer to be higher than that of the first i-type layer, the output of the solar cell is improved.

Hereinafter, an embodiment for carrying out the present invention will be described in detail with reference to the accompanying drawing. In the explanations of the figures, the same elements shall be denoted by the same reference numerals, and duplicative explanations will be omitted appropriately.

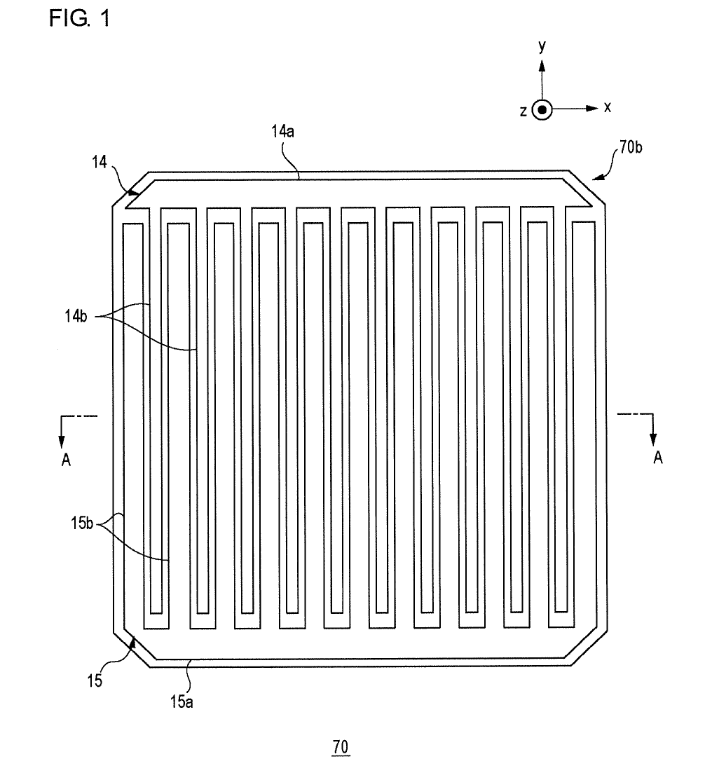

FIG. 1 is a plan view illustrating a solar cell 70 according to the embodiment and illustrates the structure of a back surface 70b of the solar cell 70. The solar cell 70 is provided with an n-side electrode 14 and a p-side electrode 15, which are provided on the back surface 70b. The n-side electrode 14 is formed in a comb-tooth shape including a bus bar electrode 14a extending in an x direction and a plurality of finger electrodes 14b extending in a y direction. In the same way, the p-side electrode 15 is formed in a comb-tooth shape including a bus bar electrode 15a extending in the x direction and a plurality of finger electrodes 15b extending in the y direction. The n-side electrode 14 and the p-side electrode 15 are formed such that the respective comb teeth engage with each other and are inserted into each other. Each of the n-side electrode 14 and the p-side electrode 15 may be formed only with a plurality of finger electrodes and may be a bus bar-less type electrode that does not have a bus bar.

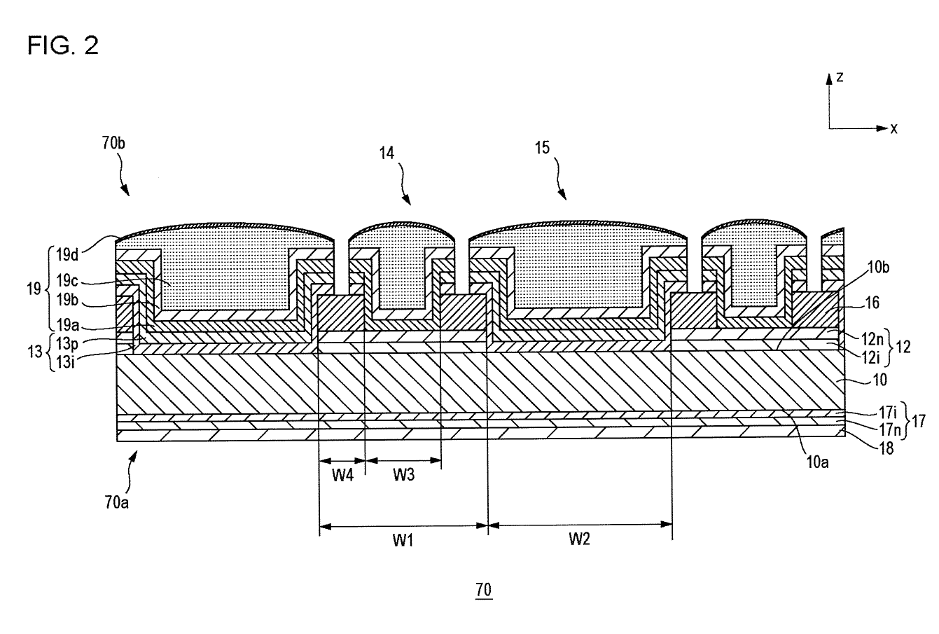

FIG. 2 is a cross-sectional view illustrating the structure of the solar cell 70 according to the embodiment and illustrates an A-A line section in FIG. 1. The solar cell 70 is provided with a semiconductor substrate 10, a first i-type layer 12i, a first conductivity type layer 12n, a second i-type layer 13i, a second conductivity type layer 13p, a first insulating layer 16, a third i-type layer 17i, a third conductivity type layer 17n, a second insulating layer 18, and an electrode layer 19. The electrode layer 19 forms the n-side electrode 14 or the p-side electrode 15. The solar cell 70 is a back surface junction type photovoltaic device where the first conductivity type layer 12n and the second conductivity type layer 13p are provided on the side of the back surface 70b.

The semiconductor substrate 10 has a first principle surface 10b provided on the side of the back surface 70b and a second principle surface 10a provided on the side of a light-receiving surface 70a. The semiconductor substrate 10 absorbs light that becomes incident on the second principle surface 10a and generates electrons and positive holes as carriers. The semiconductor substrate 10 is formed of a crystalline semiconductor material of n-type or p-type conductivity. The semiconductor substrate 10 in the embodiment is an n-type monocrystalline silicon substrate.

The light-receiving surface 70a means a principal surface on which light (sunlight) mainly becomes incident in the solar cell 70 and, specifically, means a surface on which the major portion of light entering the solar cell 70 becomes incident. On the other hand, the back surface 70b means the other principal surface opposite to the light-receiving surface 70a.

A texture structure for efficiently leading light that becomes incident on the light-receiving surface 70a is formed on the second principle surface 10a. In the present embodiment, by performing anisotropic etching on the surface of a monocrystalline silicon substrate whose substrate plane direction is a (100) plane with an alkaline solution such as a potassium hydroxide (KOH) solution, a texture structure formed with a (111) plane is formed. On the other hand, the first principle surface 10b on the side of the back surface 70b is formed with a flat (100) plane. Therefore, while the first principle surface 10b is a flat surface, the second principle surface 10a is a texture surface.

A first stack 12 and a second stack 13 are formed on the first principle surface 10b of the semiconductor substrate 10. The first stack 12 and the second stack 13 are formed in a comb-tooth shape so as to correspond to the n-side electrode 14 and the p-side electrode 15, respectively, and so as to be inserted into each other. Therefore, a first region W1 in which the first stack 12 is provided and a second region W2 in which the second stack 13 is provided are arrayed alternately in the x direction on the first principle surface 10b. Further, the first stack 12 and the second stack 13 that are adjacent to each other in the x direction are provided being in contact with each other. Therefore, in the present embodiment, the entirety of the first principle surface 10b is substantially covered by the first stack 12 and the second stack 13.

The first stack 12 is formed of the first i-type layer 12i formed on the first principle surface 10b and the first conductivity type layer 12n formed on the first-type layer 12i. The first i-type layer 12i is formed of a substantially intrinsic amorphous semiconductor (hereinafter, an intrinsic semiconductor is also referred to as “i-type layer”). In the present embodiment, it is assumed that an “amorphous semiconductor” includes a microcrystalline semiconductor. A microcrystalline semiconductor is a semiconductor where semiconductor crystals are deposited in an amorphous semiconductor.

The first i-type layer 12i is formed of i-type amorphous silicon containing hydrogen (H) and has a thickness of, for example, about several nm to 25 nm. Also, the first i-type layer 12i has a region where the oxygen concentration is high (a high oxygen concentration region) at an interface with the first principle surface 10b. The high oxygen concentration region is formed by, for example, introducing gas containing oxygen (O) in the beginning of the formation of the first i-type layer 12i or oxidizing the first principle surface 10b with an oxidizing agent. A method of forming the first i-type layer 12i is not particularly limited. For example, the first i-type layer 12i can be formed by a chemical vapor deposition (CVD) method such as a plasma CVD method. In this specification, the oxygen concentration in the high oxygen concentration region of the first i-type layer 12i is also referred to as “first oxygen concentration D1”.

The first conductivity type layer 12n is formed of an amorphous semiconductor to which an n-type dopant has been added whose conductivity type is the same as that of the semiconductor substrate 10. The first conductivity type layer 12n in the present embodiment is formed of n-type amorphous silicon containing hydrogen. The first conductivity type layer 12n has a thickness of, for example, about 2 nm to 50 nm.

The first insulating layer 16 is formed on the first stack 12. The first insulating layer 16 is not provided in a third region W3, which corresponds to a central part of the first region W1 in the x direction, and is provided in a fourth region W4, which corresponds to the opposite ends of the first region W1 excluding the third region W3. The width of the fourth region W4 in which the first insulating layer 16 is formed is, for example, about one third of the width of the first region W1. The third region W3 in which the first insulating layer 16 is not provided is, for example, about one third of the width of the first region W1.

The first insulating layer 16 is formed of, for example, silicon oxide (SiO₂), silicon nitride (SiN), silicon oxynitride (SiON), or the like. The first insulating layer 16 is desirably formed of silicon nitride and preferably contains hydrogen.

In the first principle surface 10b, the second stack 13 is formed in the second region W2 in which the first stack 12 is not provided and is formed on the ends in the fourth region W4 in which the first insulating layer 16 is provided. Thus, the ends of the second stack 13 are provided to overlap the first stack 12 in a height direction (z direction).

The second stack 13 is formed of a second i-type layer 13i formed on the first principle surface 10b and a second conductivity type layer 13p formed on the second i-type layer 13i. The second i-type layer 13i is formed of i-type amorphous silicon containing hydrogen and has a thickness of, for example, about several nm to 25 nm. Also, the second-type layer 13i has a high oxygen concentration region at an interface with the first principle surface 10b. In the same way as in the first i-type layer 12i, the high oxygen concentration region is formed by introducing gas containing oxygen (O) in the beginning of the formation or oxidizing the first principle surface 10b with an oxidizing agent. In this specification, the oxygen concentration in the high oxygen concentration region of the second i-type layer 13i is also referred to as “second oxygen concentration D2”.

The second conductivity type layer 13p is formed of an amorphous semiconductor to which a p-type dopant has been added whose conductivity type is different from that of the semiconductor substrate 10. The second conductivity type layer 13p in the present embodiment is formed of p-type amorphous silicon containing hydrogen. The second conductivity type layer 13p has a thickness of, for example, about 2 nm to 50 nm.

The n-side electrode 14 that collects electrons is formed on the first conductivity type layer 12n. The A-side electrode 15, which collects positive holes, is formed on the second conductivity type layer 13p. A groove is formed between the n-side electrode 14 and the p-side electrode 15, and the electrodes are electrically insulated from each other. In the present embodiment, the n-side electrode 14 and the p-side electrode 15 are formed of a stack of four conductive layers: a first conductive layer 19a through a fourth conductive layer 19d.

The first conductive layer 19a is formed of, for example, a transparent conductive oxide (TCO) such as a stannic oxide (SnO2), a zinc oxide (ZnO), an indium tin oxide (ITO), or the like. In the present embodiment, the first conductive layer 19a is formed of an indium tin oxide and has a thickness of, for example, about 50 nm to 150 nm.

The second conductive layer 19b through the fourth conductive layer 19d are conductive materials that contain metals such as copper (Cu), tin (Sn), gold (Au), silver (Ag) or the like. In the present embodiment, the second conductive layer 19b and the third conductive layer 19c are formed of copper, and the fourth conductive layer 19d is formed of tin. The second conductive layer 19b, the third conductive layer 19c, and the fourth conductive layer 19d have a thickness of about 50 nm to 1000 nm, a thickness of about 10 μm to 20 μm, and a thickness of about 1 μm to 5 μm, respectively.

The method of forming the first conductive layer 19a through the fourth conductive layer 19d is not particularly limited. For example, the first conductive layer 19a through the fourth conductive layer 19d can be formed by a thin film formation method such as sputtering, chemical vapor deposition, or the like or by a plating method or the like. In the present embodiment, the first conductive layer 19a and the second conductive layer 19b are formed by a thin film formation method, and the third conductive layer 19c and the fourth conductive layer 19d are formed by a plating method.

The third i-type layer 17i is provided on the second principle surface 10a of the semiconductor substrate 10. The third-type layer 17i is formed of i-type amorphous silicon containing hydrogen and has a thickness of, for example, about several nm to 25 nm. Also, on the third i-type layer 17i, a high oxygen concentration region is formed at an interface with the second principle surface 10a. In the same way as in the first i-type layer 12i, the high oxygen concentration region is formed by introducing gas containing oxygen (O) in the beginning of the formation or oxidizing the first principle surface 10b with an oxidizing agent. In this specification, the oxygen concentration in the high oxygen concentration region of the third i-type layer 17i is also referred to as “third oxygen concentration D3”.

On the third i-type layer 17i, the third conductivity type layer 17n is provided. The third conductivity type layer 17n is formed of an amorphous semiconductor to which an n-type dopant has been added whose conductivity type is the same as that of the semiconductor substrate 10. The third conductivity type layer 17n in the present embodiment is formed of n-type amorphous silicon containing hydrogen and has a thickness of, for example, about 2 nm to 50 nm. The third stack 17 is formed of the third i-type layer 17i formed on the second principle surface 10a and the third conductivity type layer 17n formed on the third i-type layer 17i.

On the third conductivity type layer 17n, the second insulating layer 18 functioning as an antireflective film and a protective film is provided. The second insulating layer 18 is formed of, for example, silicon oxide, silicon nitride, silicon oxynitride, or the like. The thickness of the second insulating layer 18 is appropriately set according to antireflection characteristics and the like for serving as an antireflective film and is set to be, for example, about 60 nm to 100 nm.

A stacked structure of the third i-type layer 17i, the third conductivity type layer 17n, and the second insulating layer 18 may function as a passivation layer of the semiconductor substrate 10.

In the present embodiment, by forming a high oxygen concentration region at an interface of the first principle surface 10b and an interface of the second principle surface 10a of the crystalline semiconductor substrate 10 so as to form minute oxide silicon regions, the photoelectric conversion efficiency is improved. In particular, by adjusting the plane direction of the principle surfaces of the semiconductor substrate 10 and adjusting the oxygen concentration in a high oxygen concentration region according to the conductivity type of an amorphous silicon layer, the photoelectric conversion efficiency is improved.

In the present embodiment, the oxygen concentration is set to be higher at the interface of the first principle surface 10b, which is a flat surface formed with a (100) plane, than at the interface of the second principle surface 10a, which is a texture plane formed with a (111) plane. In other words, the oxygen concentration is set to be higher in the respective high oxygen concentration regions of the first i-type layer 12i and the second i-type layer 13i on the first principle surface 10b than the high oxygen concentration region of the third i-type layer 17i on the second principle surface 10a. Therefore, the respective oxygen concentrations of the first i-type layer 12i, the second i-type layer 13i, and the third i-type layer 17i are adjusted such that relationships where the first oxygen concentration D1>the third oxygen concentration D3 and the second oxygen concentration D2>the third oxygen concentration D3 are established.

In the present embodiment, the oxygen concentration is set to be higher in the high oxygen concentration region of the second-type layer 13i on which a p-type amorphous silicon layer is formed than the high oxygen concentration region of the first i-type layer 12i and the third i-type layer 17i on which an n-type amorphous silicon layer is formed. Therefore, the respective oxygen concentrations of the first i-type layer 12i, the second i-type layer 13i, and the third i-type layer 17i are adjusted such that relationships where the second oxygen concentration D2>the first oxygen concentration D1 and the second oxygen concentration D2>the third oxygen concentration D3 are established.

Based on the above concentration relationships, in the present embodiment, the respective oxygen concentrations of the first i-type layer 12i, the second i-type layer 13i, and the third i-type layer 17i are preferably adjusted such that a relationship where the second oxygen concentration D2>the first oxygen concentration D1>the third oxygen concentration D3 is established. By adjusting the oxygen concentration in this manner, the photoelectric conversion efficiency of the solar cell 70 can be increased, and the output characteristics can be improved.

On the other hand, when the oxygen concentration of the high oxygen concentration region is increased too much, oxygen that is excessively incorporated in the amorphous silicon layer may act as impurities, leading defects and/or the formation of a high resistance region. More specifically, the concentration of oxygen included in the amorphous silicon layer exceeding about 2*10²¹/cm³ may have an effect on the improvement of the photoelectric conversion efficiency. Accordingly, in the present embodiment, an oxygen concentration is desirably adjusted such that the second oxygen concentration D2 in the second i-type layer 13i having relatively high oxygen concentration is 2*10²¹/cm³ or less. In the same way, an oxygen concentration is desirably adjusted such that the first oxygen concentration D1 in the first i-type layer 12i and the third oxygen concentration D3 in the third i-type layer 17i are also 2*10²¹/cm³ or less.

In an exemplary variation, each amorphous silicon layer may be formed such that one more of the three conditions, the second oxygen concentration D2>the first oxygen concentration D1, the first oxygen concentration D1>the third oxygen concentration D3, and the second oxygen concentration D2>the third oxygen concentration D3, is established. Also in this case, oxygen concentration is desirably adjusted such that the oxygen concentration of the first i-type layer 12i, the oxygen concentration of the second i-type layer 13i, and the oxygen concentration of the third i-type layer 17i are 2*10²¹/cm³ or below.

The present invention has been described by referring to each of the above-described embodiments. However, the present invention is not limited to the above-described embodiments only, and those resulting from any combination of them as appropriate or substitution are also within the scope of the present invention.

An aspect of the embodiment is as shown in the following. A solar cell 70 according to an aspect includes: a semiconductor substrate 10 formed of n-type crystalline silicon; a first stack 12 formed of amorphous silicon in a first region W1 on a first principle surface 10b of the semiconductor substrate 10; a second stack 13 formed of amorphous silicon in a second region W2 different from the first region W1 on the first principle surface; and a third stack 17 formed of amorphous silicon on a second principle surface 10a of the semiconductor substrate 10 opposite from the first principle surface 10b, wherein the second stack 13 has an oxygen concentration that is higher than that of the first stack 12.

The second stack 13 may have an oxygen concentration that is higher than that of the third stack 17.

The first stack 12 may have an oxygen concentration that is higher than that of the third stack 17.

The first stack 12 includes a first-type layer 12i formed of i-type amorphous silicon in the first region W1 and a first conductivity type layer 12n formed of n-type amorphous silicon on the first i-type layer 12i. The second stack 13 includes a second i-type layer 13i formed of i-type amorphous silicon in the second region W2 and a second conductivity type layer 13p formed of p-type amorphous silicon on the second i-type layer 13i.

The second i-type layer 13i may have an oxygen concentration of 2*10²¹/cm³ or less.

The third stack 17 may include a third i-type layer 17i formed of i-type amorphous silicon on the second principle surface 10a.

The first principle surface 10b may be a texture surface, and the second principle surface 10a may be a flat surface.

It should be understood that the invention is not limited to the above-described embodiment, but may be modified into various forms on the basis of the spirit of the invention. Additionally, the modifications are included in the scope of the invention.

1. A solar cell comprising:
a semiconductor substrate formed of n-type crystalline silicon;
a first stack formed of amorphous silicon in a first region on a first principle surface of the semiconductor substrate;
a second stack formed of amorphous silicon in a second region different from the first region on the first principle surface; and
a third stack formed of amorphous silicon on a second principle surface of the semiconductor substrate opposite from the first principle surface,
wherein the second stack has an oxygen concentration that is higher than that of the first stack.

2. The solar cell according to claim 1, wherein the second stack has an oxygen concentration that is higher than that of the third stack.

3. The solar cell according to claim 1, wherein the first stack has an oxygen concentration that is higher than that of the third stack.

4. The solar cell according to claim 1,
wherein the first stack includes a first-type layer formed of i-type amorphous silicon in the first region and a first conductivity type layer formed of n-type amorphous silicon on the first i-type layer, and
wherein the second stack includes a second i-type layer formed of i-type amorphous silicon in the second region and a second conductivity type layer formed of p-type amorphous silicon on the second i-type layer.

5. The solar cell according to claim 4, wherein the second i-type layer has an oxygen concentration of 2*10²¹/cm³ or less.

6. The solar cell according to claim 1, wherein the third stack includes a third i-type layer formed of i-type amorphous silicon on the second principle surface.

7. The solar cell according to claim 1, wherein the first principle surface is a texture surface, and wherein the second principle surface is a flat surface.
